(19) United States
(12) Patent Application Publication
(10) Pub. No.: US 2008/0178055 A1
(43) Pub. Date: Jul. 24, 2008

(54) Test pattern generation circuit having plural pseudo random number generation circuits supplied with clock signals at different timing respectively

(75) Inventor: Hisashi Nakamura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/010,264

(22) Filed: Jan. 23, 2008

(30) Foreign Application Priority Data
Jan. 24, 2007 (JP) 2007-014025

(51) Int. Cl. G01R 31/3183; G06F 11/263

(52) U.S. Cl. 714/735; 714/739; 714/E11.177

(57) ABSTRACT

A test pattern generation circuit has multiple pseudo random number generation circuits and a clock control circuit. The pseudo random number generation circuits are provided corresponding to the respective signal lines in a bus wiring, and have predetermined first initial values, which take the same value. In response to first clock signals, the pseudo random number generation circuits generate pseudo random numbers including the first initial values as starting values. According to the value of a control signal, the clock control circuit determines the output-start timings of the first clock signals to be respectively provided to the multiple pseudo random number generation circuits.

### BACKGROUND OF THE INVENTION

1. Field of the Invention

A test pattern generation circuit according to the present invention particularly relates to a test pattern generation circuit and for giving pseudo random numbers as test patterns to an interface circuit having a multiple-bit configuration.

2. Description of Related Art

Among malfunctions in a semiconductor device, a malfunction in an interface circuit connected to a bus wiring has been a problem in recent years. The interface circuit connected to the bus wiring transmits and receives random data pieces to and from the bus wiring. A certain order of transmitted/received data pieces may cause interference between the data pieces in the interface circuit, thereby leading to an occurrence of a malfunction in which an error occurs in the transmitted/received data pieces. The interface circuit is required to perform excellent transmission and reception even for various types of data that are likely to cause a malfunction as described above. For this reason, there has been a demand for a test circuit and a test pattern generation circuit for performing a test on an interface circuit by using such various types of data. Accordingly, circuits described in the below-mentioned Patent Documents 1 to 4 have been proposed.

FIG. 18 shows a block diagram of a test circuit 110 disclosed in Patent Document 1. The test circuit 110 is incorporated in a semiconductor device 1001, and generates random test patterns and signatures for test patterns inputted through an interface circuit 120. At this time, the test circuit 110 conducts the random test patterns by use of a pattern generation unit 111 and a shift register 112. The pattern generation unit 111 includes an LFSR (Linear Feedback Shift Register) 116 that generates pseudo random numbers having a certain seed value (hereinafter, referred to as a Seed value) as a starting value, and thereby generates the pseudo random numbers serially. The shift register 112 converts the serial pseudo random numbers into parallel pseudo random numbers by rearranging the serial pseudo random numbers by use of a flip-flop connected in series. Then, the output from the pattern generation unit 111 and the output from the shift register 112 are inputted in parallel into a data combining unit 113, whereby test patterns having randomness are inputted to the interface circuit 120 connected to a bus wiring. In this way, the test circuit 110 can input a data sequence having randomness into the interface circuit 120.

In addition, in a case of a test circuit according to the Patent Document 2, a test pattern generator and a semiconductor device to be tested are prepared individually. The test pattern generator generates pseudo random numbers having a certain Seed value as a starting value and outputs the pseudo random numbers to the semiconductor device. The semiconductor device includes an expected value generation circuit with a circuit configuration supporting the test pattern generator. Then, a comparator compares tests pattern inputted through an interface circuit included in the semiconductor device with the output of the expected value generation circuit. In this way, in the conventional example 2, the interface circuit is tested by use of a random data sequence.

In the Patent Documents 1 and 2, the pseudo random numbers are used as the test patterns. Other examples of a circuit that generates such pseudo random numbers are disclosed in Patent Documents 3 and 4.

### [Patent Document 1] Japanese Patent Application Laid-open Publication No. 2006-78447

### [Patent Document 2] Japanese Patent Application Laid-open Publication No. 2005-339675

[Patent Document 3] Japanese Patent Application Laid-open Publication No. Hei 11-85475

### [Patent Document 4] Japanese Patent Application Laid-open Publication No. 2003-330704

Application of the Patent Documents 1 to 4 secures randomness of data in a data sequence direction. However, it is not possible to set multiple Seed values for the pattern generation circuit or the pattern generation unit of each of the Patent Documents 1 to 4. Accordingly, each of the Patent Documents 1 to 4 can generate only the pseudo random numbers based on its circuit configuration. For this reason, combinations of data pieces for signal lines in the bus wiring (hereinafter, referred to as a bus width direction) are limited. For example, a test pattern having a certain combination cannot be generated intentionally. Hence, the Patent Documents 1-4 have a problem that a test coverage in a bus width direction in a test of an interface circuit cannot be increased.

### SUMMARY

A test pattern generation circuit has multiple pseudo random number generation circuits and a clock control circuit. The pseudo random number generation circuits are provided corresponding to the respective signal lines in a bus wiring, and have predetermined first initial values, which take the same value. In response to first clock signals, the pseudo random number generation circuits generate pseudo random numbers including the first initial values as starting values. According to the value of a control signal, the clock control circuit determines the output-start timings of the first clock signals to be respectively provided to the multiple pseudo random number generation circuits.

According to the test pattern generation circuit of the present invention, operation start timings of the plurality of pseudo random number generation circuits having the common first initial value can be set as required. This allows combinations of patterns to be set as required, the patterns generated at a certain time point by the plurality of pseudo random number generation circuits.

Moreover, a test circuit includes the test pattern generation circuit of the present invention, a comparator and a result holding circuit. The comparator compares pseudo random numbers inputted via the interface circuit, with pseudo random numbers outputted by the plurality of pseudo random number generation circuits. The result holding circuit holds test results outputted by the comparator and outputs the test results. This test circuit allows a feedback test with high test coverage to be performed.

According to a test pattern generation circuit and a test circuit of the present invention, it is possible to perform a feedback test with high test coverage by improving both of the randomness in the data sequence direction and the randomness of combinations of data pieces in a bus width direction.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a block diagram of a test pattern generation circuit according to Embodiment 1;

FIG. 2 is a block diagram of a first clock control circuit according to Embodiment 1;

FIG. 3 shows a timing chart indicating operations in a case where the value of a first control signal is “1” in the first clock control circuit according to Embodiment 1;

FIG. 4 shows a timing chart indicating operations in a case where the value of the first control signal is “4” in the first clock control circuit according to Embodiment 1;

FIG. 5 is a block diagram of a test pattern generation circuit according to Embodiment 2;

FIG. 6 is a block diagram of a first clock control circuit according to Embodiment 2;

FIG. 7 shows a timing chart indicating operations in a case where the value of a first control signal is “1” in the first clock control circuit according to Embodiment 2;

FIG. 8 is a block diagram of a test pattern generation circuit according to Embodiment 3;

FIG. 9 is a block diagram of a second clock control circuit according to Embodiment 3.

FIG. 10 shows a timing chart indicating operations in a case where the value of a second control signal is “1” in the second clock control circuit according to Embodiment 3;

FIG. 11 shows a timing chart indicating operations in a case where the value of the second control signal is “0” in the second clock control circuit according to Embodiment 3;

FIG. 12 is a block diagram showing a different example of the test pattern generation circuit according to Embodiment 3;

FIG. 13 shows a timing chart indicating operations in a case where the value of a first control signal is “1” in the different example of the second clock control circuit according to Embodiment 3;

FIG. 14 is a block diagram of a test pattern generation circuit according to Embodiment 4;

FIG. 15 is a timing chart showing operations of a test pattern generation circuit according to Embodiment 4;

FIG. 16 is a block diagram of a test circuit according to Embodiment 5;

FIG. 17 is a block diagram in a case where the test pattern generation circuit 2 is employed in the test circuit according to Embodiment 5; and

FIG. 18 is a block diagram of a test circuit according to a related example.

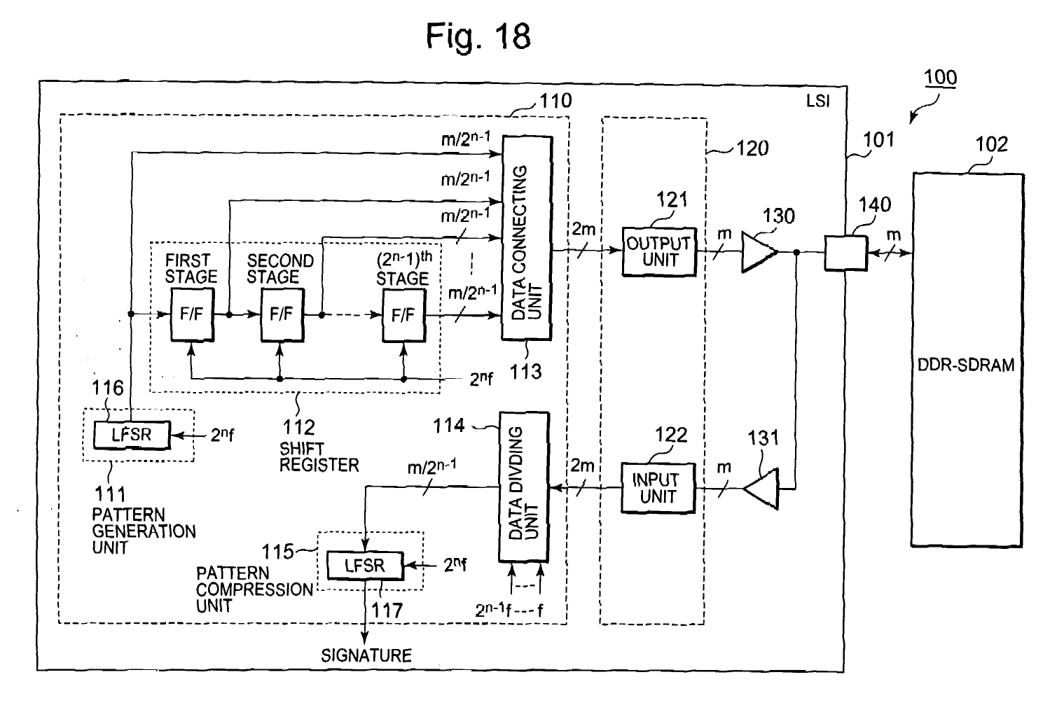

### DETAILED DESCRIPTION OF THE EXEMPLARY EMBODIMENT

### Embodiment 1

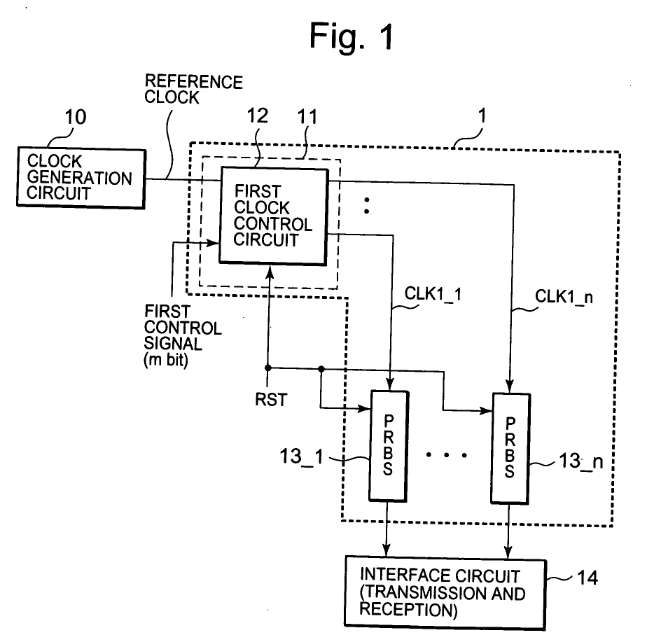

FIG. 1 shows a block diagram of a test pattern generation circuit 1 according to the present invention. As shown in FIG. 1, the test pattern generation circuit 1 includes a clock control circuit 11 and pseudo random number generation circuits (PRBSs in the drawing) 13_1 to 13_n. The output of each of the pseudo random number generation circuits is connected to a corresponding interface channel. In the following description, n and m each denote an integer. Moreover, a clock generation circuit 10 and an interface circuit 14 are connected to the test pattern generation circuit 1.

The clock generation circuit 10 outputs reference clocks having certain frequency. This embodiment employs the clock generation circuit 10 configured to output reference clocks after a reset signal RST, which will be described later, changes from a low level to a high level.

The interface circuit 14 is a circuit to be tested, and is connected to a bus wiring (not illustrated). Moreover, multiple channels are included in the interface circuit 14 to be tested by the test pattern generation circuit and the test circuit according to the present invention, and each of the channels includes a transmission circuit and a receiving circuit.

The clock control circuit 11 includes a first clock control circuit 12. The first clock control circuit 12 generates multiple first clock signals CLK1_1 to CLK1_n in response to the reference clocks. Moreover, the first clock control circuit 12 sets each of output-start timings of the multiple first clock signals as required according to the value of a first control signal. Then, the first clock signals CLK1_1 to CLK1_n are respectively inputted, as clocks, into the pseudo random number generation circuits 13_1 to 13_n that are provided corresponding to the first clock signals CLK1_1 to CLK1_n. Incidentally, the first control signal is composed of a control signal having a multi-bit structure (for example, m bits). Accordingly, in this embodiment, the first clock control circuit 12 sets the output-start timings of the first clock signals CLK1_1 to CLK1_n according to a value indicated by the m bits. Moreover, the first clock control circuit 12 receives the reset signal RST. This reset signal RST is also supplied to each of the pseudo random number generation circuits 13_1 to 13_n. This reset signal RST will be described later.

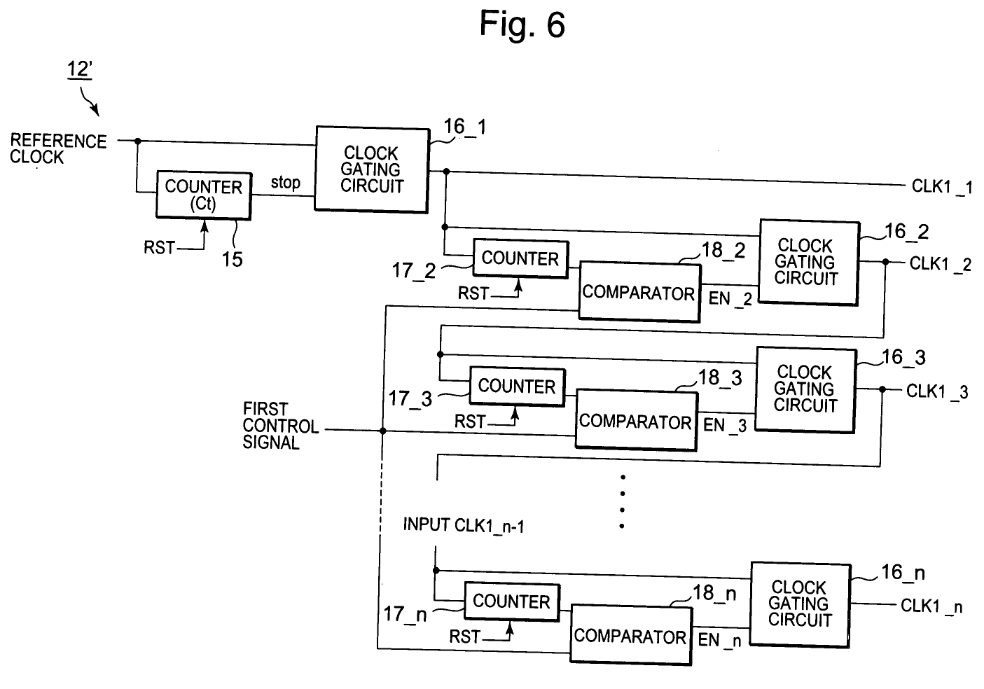

Each of the pseudo random number generation circuits 13_1 to 13_n is a circuit shown, for example, in FIG. 6 of Document 4, and outputs the same pseudo random number data sequence (a data sequence called a PRBS (a Pseudo Random Binary Sequence)) containing, as a starting value, the Seed value (hereinafter, referred to as a first initial value) taking the same value. In this embodiment, each of the pseudo random number generation circuits 13_1 to 13_n internally includes an LFSR (Linear Feedback Shift Register) configured of a shift register with feedback via an exclusive OR (ExOR) circuit. At a reset time (while the reset signal RST is at a low level), each of the pseudo random number generation circuits 13_1 to 13_n has the first initial value by initializing its internal register (LFSR). Then, after the reset is released, the pseudo random number generation circuits 13_1 to 13_n generate and output pseudo random numbers in response to the respective first clock signals CLK1_1 to CLK1_n. Moreover, since the pseudo random number generation circuits 13_1 to 13_n are provided corresponding to the respective channels in the interface circuit 14, the pseudo random number generation circuits 13_1 to 13_n are provided corresponding to the respective signal lines in the bus wiring connected to the interface circuit 14. In other words, the number of pseudo random number generation circuits 13_1 to 13_n is equal to the number of the signal lines in the bus wiring.

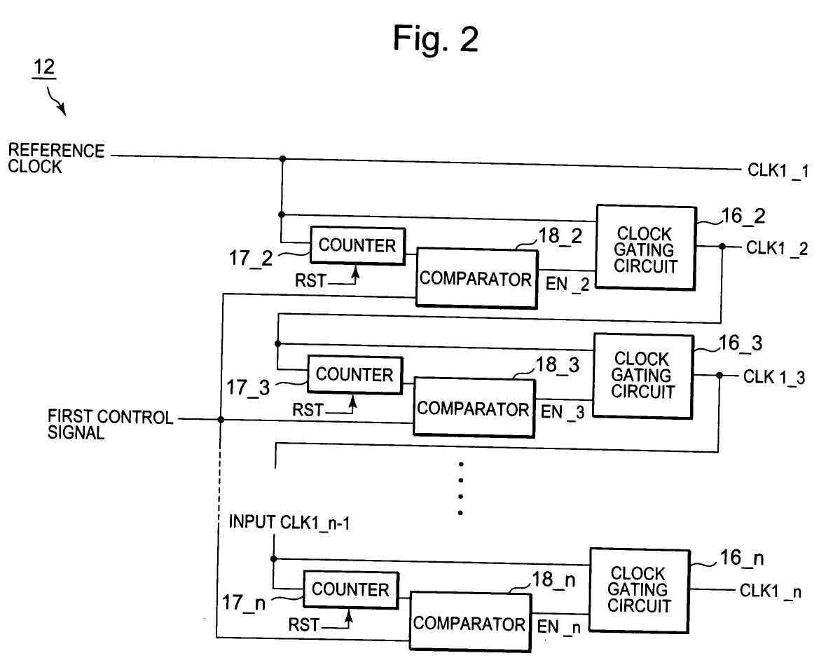

Here, the first clock control circuit 12 is described in more detail. FIG. 2 shows a block diagram of the first clock control circuit 12. As shown in FIG. 2, the first clock control circuit includes counters 17_2 to 17_n, clock gating circuits 16_2 to 16_n and comparators 18_2 to 18_n.

In this embodiment, the first clock control circuit 12 outputs the inputted reference clocks as the first clock signals CLK1_1 to CLK1_n. Each of the counters 17_2 to 17_n receives the reset signal RST, and keeps holding the initial value “0” as the count value while the reset signal RST is staying at the low level. After the reset signal RST becomes the high level, each of the counters 17_2 to 17_n counts the number of clocks of a corresponding one of the first clock signals CLK1_1 to CLK1_n−1. For example, the counter 17_2 is provided corresponding to the clock gating circuit 16_2 that outputs the first clock signal CLK1_2, and counts the number of clocks of the first clock signal CLK1_1. Each of the comparators 18_2 to 18_n compares the count value outputted by a corresponding one of the counters with the value of the first control signal, and outputs a corresponding one of enable signals EN_2 to EN_n at a timing when the count value matches with the value of the first control signal. For example, the comparator 18_2 compares the count value outputted by the counter 17_2 with the value of the first control signal, and outputs the enable signal EN_2 at a timing when the count value matches with the value of the first control signal. Incidentally, the counters 17_2 to 17_n of this embodiment are each configured to keep the count value after the count value matches with the value of the first control signal.

The clock gating circuits 16_2 to 16_n are AND gates or the like, and output the first clock signals CLK1_1 to CLK1_n−1 as corresponding first clock signals CLK1_2 to CLK1_n, respectively, in response to the inputted corresponding enable signals EN_2 to EN_n, respectively. For example, when the enable signal EN_2 is at the high level, the clock gating circuit 16_2 outputs the first clock signal CLK1_1 as the first clock signal CLK1_2. On the other hand, when the enable signal EN_2 is at the lower level, the clock gating circuit 16_2 does not output any clock by regarding the output as the low level.

Hereinafter, consider a case where: the interface circuit 14 includes 4 channels (n=4); the pseudo random number generation circuits each include 7 stages (the order k=7, that is, composed of registers at 7 stages); and the first control signal contains 6 bits (m=6). At this time, the single pseudo random number generation circuit 13_1 generates 2⁷−1=127 of pseudo random number sequences. In other words, the single pseudo random number generation circuit 13_1 generates the pseudo random numbers having one cycle of 127 clocks. Moreover, the first clock control circuit 12 sets the output-start timings of the first clock signals CLK1_1 to CLK1_n according to a value indicated by 6 bits.

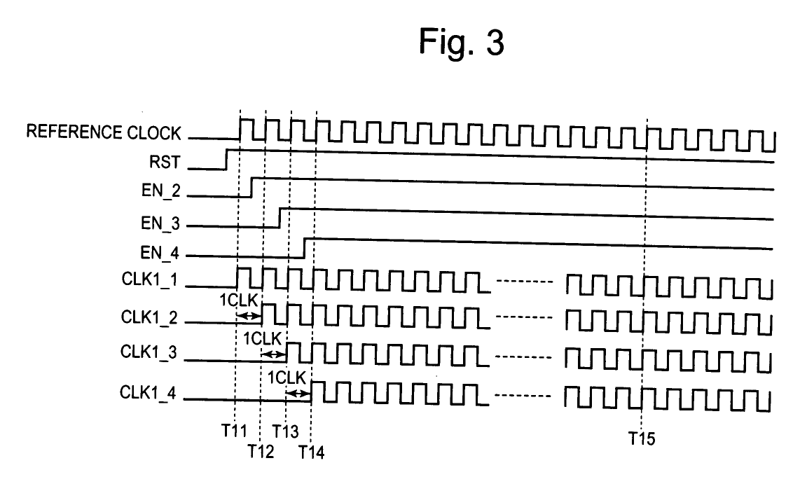

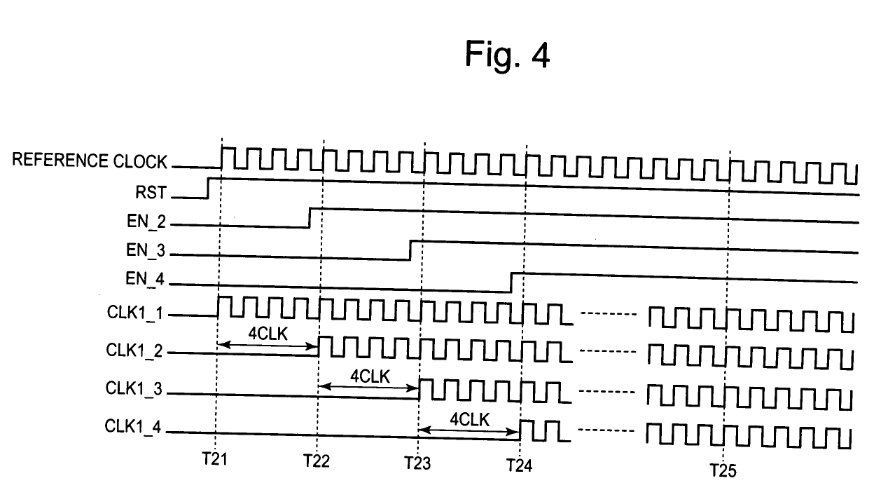

FIGS. 3 and 4 show timing charts of operations of the first clock control circuit 12 in the above case. The timing chart shown in FIG. 3 shows operations of the first clock control circuit 12 in a case where the first control signal indicates “1” (for example, “000001”). The timing chart shown in FIG. 4 shows operations of the first clock control circuit 12 in a case where the first control signal indicates “4” (for example, “000100”). Incidentally, since FIGS. 3 and 4 show the cases where n=4, the first clock control circuit 12 outputs the first clock signals CLK1_1 to CLK1_4. The operations of the first clock control circuit 12 are described by referring to FIGS. 3 and 4.

To begin with, the operations shown in FIG. 3 are described. Before starting the operations, the first clock control circuit 12 sets the reset signal RST to the low level, thereby causing the counter values of the counters 17_2 to 17_n (n=4 in this description) to be “0.” Then, the first clock control circuit 12 sets the reset signal RST to the high level, thereby releasing the reset. After releasing the reset, the first clock control circuit 12 receives the reference clock from the clock generation circuit 10. In response to the release of the reset and the application of the reference clock, the first clock control circuit 12 outputs the reference clock as a first clock CLK1_1 (a timing T11).

Moreover, since the value of the first control signal is “1,” the comparator 18_2 sets the enable signal EN_2 to the high level when the count value of the counter 17_2 becomes “1.” Accordingly, the clock gating circuit 16_2 starts outputting the first clock signal CLK1_2 after a delay of a time period equivalent to one clock of the reference clocks from the first clock signal CLK1_1 (at a timing T12).

Thereafter, the first clock signal CLK1_3 and the first clock signal CLK1_4 are outputted as similar to the first clock signal CLK1_2. More precisely, the start of outputting the first clock signal CLK1_3 is delayed by the time period equivalent to one clock of the reference clocks after the first clock signal CLK1_2 (a timing T13). The start of outputting the first clock signal CLK1_4 is delayed by the time period equivalent to one clock of the reference clocks after the first clock signal CLK1_3 (a timing T14). In short, the first clock signals CLK1_1 to CLK1_4 are sequentially outputted after a delay of clocks, the number of which corresponds to the value of the first control signal.

Here, a timing T15 is set to a time point after a timing T14 (including T14) when the last first clock signals are inputted to the pseudo random number generation circuits. After the timing T15, the first clock signals CLK1_1 to CLK1_4 are applied to all the pseudo random number generation circuits for one or more cycles. In addition, after the timing T15, test patterns to be used for an actual test are generated. Note that a period from the timing T11 to the timing T15 shown in FIG. 3 is referred to below as a test pattern initial value setting period in this description.

Subsequently, the operations shown in FIG. 4 are described. In FIG. 4, since the value of the first control signal is “4,” the comparator 18_2 causes the enable signal EN_2 to be the high level when the count value of the counter 17_2 reaches “4.” Accordingly, the clock gating circuit 16_2 starts outputting the first clock signal CLK1_2 after a delay of a time period equivalent to 4 clocks of the reference clocks from the first clock signal CLK1_1 (at a timing T22). The other operations are the same as shown in FIG. 3, and timings T21, T22, T23, T24 and T25 correspond to the timings T11, T12, T13, T14 and TI5, respectively. Note that, as is the case with the timing T15, the timing T25 is set to a time point after the timing T24 (including T24) when the last first clock signal is inputted to the pseudo random number generation circuit.

As described above, the first clock control circuit sets the output-start timings of the first clock signals CLK1_1 to CLK1_n according to the value of the first control signal. By use of the operations of the first clock control circuit, the test pattern generation circuit 1 of this embodiment sets a random number generation starting value (hereinafter, referred to as a second initial value) of each of the pseudo random number generation circuits 13_1 to 13_n at a time of starting a test. In short, the initial values (second initial values) of the test patterns to be used in an actual test are generated and set at the timings T15 and T25 as described above.

Here, descriptions are given for test patterns used in a second initial value setting operation and in a test. In the first place, the second initial value setting operation is explained. The pseudo random number generation circuits 13_1 to 13_n of this embodiment each output a 7-stage PRBS. Accordingly, an outputted data sequence contains 127 pieces of data. Here, the data pieces of the data sequence are denoted by D1 to D127. When the starting value is the first initial value, each of the pseudo random number generation circuits 13_1 to 1_n outputs data D1 to Data D127 sequentially and repeatedly by using the data D1 as data used at a time of starting the operation.

In a case where the first clock signals CLK1_1 to CLK1_n outputted by the first clock control circuit 12 are given to the pseudo random number generation circuits 13_1 to 13_n, the outputs OUT1 to OUT4 of the pseudo random number generation circuits 13_1 to 13_4 are “D4, D3, D2 and D1,” respectively, in the order from OUT1, for example, at the timing T14 shown in FIG. 3. Here, in a case where the timing T15 is set to the same time point as the timing T14, the outputs OUT1 to OUT4 of the pseudo random number generation circuits 13_1 to 13_4 are “D4, D3, D2 and D1” in the order from OUT1. Instead, in a case where the timing T15 is set to a time point when 127 clocks of the reference clock passes after the timing T11, the outputs OUT1 to OUT4 are “D127, D126, D125 and D124,” respectively. In this embodiment, as described above, the initialization of the pseudo random number generation circuits 13_1 to 13_4 is completed at the timing T15, and the values of OUT1 to OUT4 at the timing T15 are given as the second initial values. Moreover, in the example shown in FIG. 4, when the timing T25 is similarly set to the same time point as the timing T24, the second initial values of the test patterns TP1 to TP4 are “D13, D9, D5 and D1” in the order from the test pattern TP1. Instead, when the timing T25 is similarly set to a time point when 127 clocks of the reference clock passes after the timing T21, the second initial values of the test patterns TP1 to TP4 are “D127, D123, D119 and D115” in the order from the test pattern TP1. Data pieces after the timing T15 are actual test patterns for the interface circuit 14. Accordingly, in a test status, the test patterns outputted by the pseudo random number generation circuits 13_1 to 13_4 after the timing T15 are sequentially given to the interface circuit 14.

As described above, in the test pattern generation circuit 1 of this embodiment, according to the value of the first control signal, the clock control circuit 11 can change each of the output-start timings of multiple first clock signals to be outputted. In addition, by operating the multiple pseudo random number generation circuits in response to the multiple first clock signals, the numbers of clocks of the first clock signals to be given to the multiple pseudo random number generation circuits can be made to take different values during the test pattern initial value setting period. Then, the second initial values are set according to the values outputted by the multiple pseudo random number generation circuits at a time of the completion of the test pattern initial value setting period. In other words, the second initial values set in the multiple pseudo random number generation circuits differ from each other according to the value of the first control signal, and the pseudo random number data sequence containing the second initial values as the starting values are generated after the test starts. In short, the test pattern generation circuit 1 according to this embodiment has a function corresponding to a function of arbitrarily setting Seed values of multiple pseudo random number generation circuits.

By use of this, the test pattern generation circuit 1 according to this embodiment can set certain combinations of data pieces in the bus width direction as required at any given time point after a test starts, the data pieces outputted by the multiple pseudo random number generation circuits. Hence, according to the test pattern generation circuit 1 of this embodiment, it is possible to give the interface circuit 14 test patterns having high randomness in the data sequence direction and high randomness in the bus width direction.

Moreover, since the test pattern generation circuit 1 includes the multiple pseudo random number generation circuits, the test pattern generation circuit 1 can generate random patterns at a high speed. In the conventional example 1, one of four random patterns outputted by the LFSR is transmitted to the interface circuit. In contrast, random patterns outputted by the test pattern generation circuit 1 can be continuously given to the interface circuit 14 without being thinned out. In the foregoing embodiment, the example has been described in which the first clock control circuit 12 outputs the multiple first clock signals at the different output-start timings. However, in a case where the value of the first control signal is set to “0,” the multiple first clock signals are outputted at the substantially same timing.

In this way, all the test patterns outputted by the pseudo random number generation circuits can be made to be the same data at any time. In other words, the test pattern generation circuit 1 of this embodiment can combine data pieces in the bus width direction with a high degree of freedom. In essence, the test pattern generation circuit 1 can intentionally generate test patterns having a certain combination.

Here, descriptions are given for the setting of the timings T15 and T25 and the setting of the bit width of the first control signal in the test pattern generation circuit 1. Each of the timings T15 and T25 is a timing when all the pseudo random number generation circuits receive the applied first clock signals CLK1_1 to CLK1_4 for one or more cycles and thus can respectively generate the pseudo random numbers. In the case of the present invention, the interface circuit has n channels and the first control signal contains m bits. For this reason, such timings can be set to a time point after the timing of application of the reference clocks of at least the number (2^{m}−1)×(n−1) of cycles.

In addition, the first control signal indicates a difference (delay) in clocks between the adjacent first clock signals in the first clock signals CLK1_1 to CLK1_n. If the pseudo random number generation circuits 13_1 to 13_n each have k stages, it suffices that the first control signal be capable of indicating 2^{k}−1 at a maximum. In other words, k may be sufficient for the bit width of the first control signal. Note that the effects of the present invention can be obtained even when the bit width has a value smaller than k.

### Embodiment 2

In the embodiment 1, the descriptions have been provided for the example in which the Seed values (second initial values) of the test patterns, which are used to test the interface circuit 14, are generated by use of the reference clocks, and in which the actual test patterns are generated by use of the reference clocks after the second initial values are generated. However, by additionally preparing test clocks, the actual test patterns can be also generated by use of the test clocks after the second initial values are generated, while the second initial values are generated by use of the reference clocks.

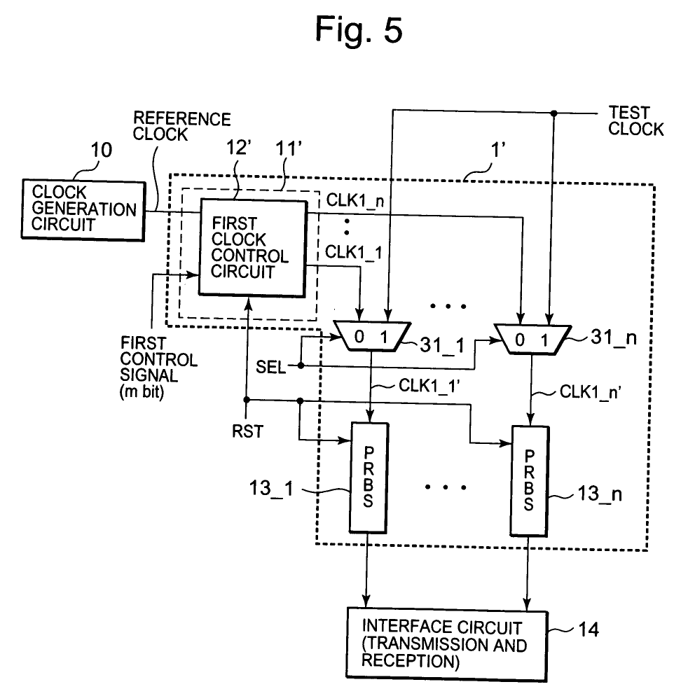

FIGS. 5 and 6 show an embodiment corresponding to this case. FIG. 5 is a block diagram of a test pattern generation circuit 1′ of Embodiment 2, and FIG. 6 is a block diagram of a first clock control circuit 12′. In Embodiment 2, selectors 31_1 to 31_n are further provided in addition to Embodiment 1 (FIG. 1), and switches between first clock signals CLK1_1 to CLK1_n, which are the outputs of the first clock control circuit 12′, and test clocks by using a selecting signal SEL. Then, the test clocks are outputted to the pseudo random number generation circuits 13_1 to 13_n as first clock signals CLK1_1′ to CLK1_n′. The first clock control circuit 12′ is a circuit shown in FIG. 6 with which the first clock control circuit 12 shown in FIG. 2 is replaced.

The difference in configuration between the first clock control circuit 12′ shown in FIG. 6 and the first clock control circuit 12 shown in FIG. 2 is that the first clock control circuit 12′ includes a counter 15 and a clock gating circuit 16_1. The clock gating circuit 16_1 is one having a function of stopping output of the first clock signal CLK1_1 in response to a stop signal of the counter 15. Except the difference described above, this first clock control circuit 12′ has the same configuration as the first clock control circuit 12.

The counter 15 is a Ct-bit counter that counts the number of reference clocks applied, for example, during the test pattern initial value setting period as described above. The reference clocks and the reset signal RST are inputted to the counter 15. Then, when the reset signal RST is at the low level, the counter 15 is initialized (the count value is set to “0”), and then counts the reference clocks inputted after the reset signal RST becomes the high level. Subsequently, when the count value becomes Ct, the counter 15 outputs a stop signal to a clock gating circuit. In this embodiment, the stop signal is provided to the clock gating circuit 16_1, the stop signal at a high level instructing the operation state, and the stop signal at a low level instructing the stop state. Moreover, the counter 15 maintains the low level until being reset, once the stop signal is switched to the low level.

The clock gating circuit 16_1 outputs the reference clocks as the first clock signal CLK1_1 when the reset signal RST and the stop signal are at the high level. Then, when the count value of the counter 15 becomes Ct, the stop signal is set to the low level. In this state, the clock gating circuit 16_1 stops the output (the low level is fixed).

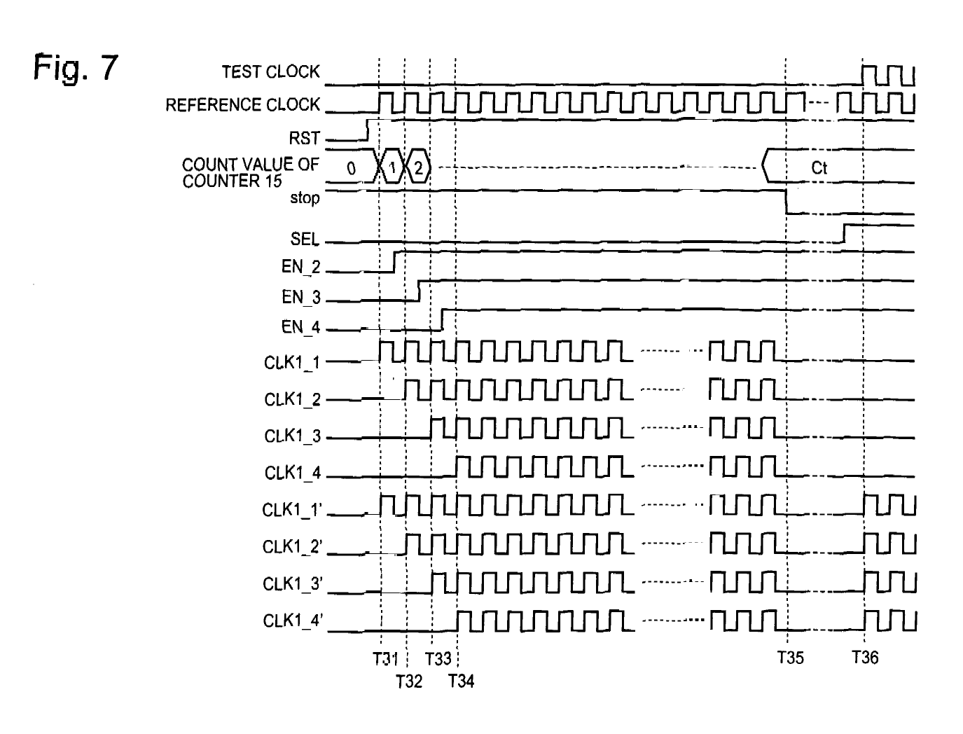

FIG. 7 is a timing chart showing operations of Embodiment 2. At a timing T35, the count value of the counter 15 reaches Ct, and then the stop signal is switched from the high level to the low level. In response to this, the second initial values are set. In addition, the first clock control circuit 12′ stops outputting the first clock signals CLK1_1 to CLK1_n to the pseudo random number generation circuits 13_1 to 13_n. At this time, the selecting signal SEL is kept at the low level until the timing T35. Thereby, to the pseudo random number generation circuits 13_1 to 13_n, the selectors 31_1 to 31n output, as the first clock signal CLK1_1′ to CLK1_n′, the first clock signals CLK1_1 to CLK1_n, which are the outputs of the first clock control circuit 12′. Subsequently, the selecting signal SEL is set to the high level at an arbitrary timing after the timing T35. In this way, the selectors 31_1 to 31_n output the test clocks, as the first clock signals CLK1_1′ to CLK1_n′, to the pseudo random number generation circuits 13_1 to 13_n (at a timing T36 in the drawing).

Here, the timing T35 is specified by Ct that is the maximum count value of the counter 15. In other words, at the timing T35, the second initial values are set in the test pattern generation circuit of the present invention.

Note that, in a case where the reference clock and the test clock are simultaneously inputted, there are problems that noise occurs at a timing when the reference clock is switched to the test clock, and that the clocks, which are not needed any longer after the switching (here, the reference clocks), function as a noise source.

In order to avoid these problems, this embodiment employs the first clock control circuit 12′ shown in FIG. 6, instead of the first clock control circuit 12 shown in FIG. 2.

However, in a case where noise that occurs at the timing of switching the clocks and between the clocks is not problematic, the first clock control circuit 12, as it is, may also be employed in Embodiment 2.

Moreover, in Embodiment 2, high-speed clocks can be used as the test clocks. Furthermore, it is possible to directly use, as the test clocks, the internal clocks of an LSI on which the test pattern generation circuit of the present invention is mounted.

### Embodiment 3

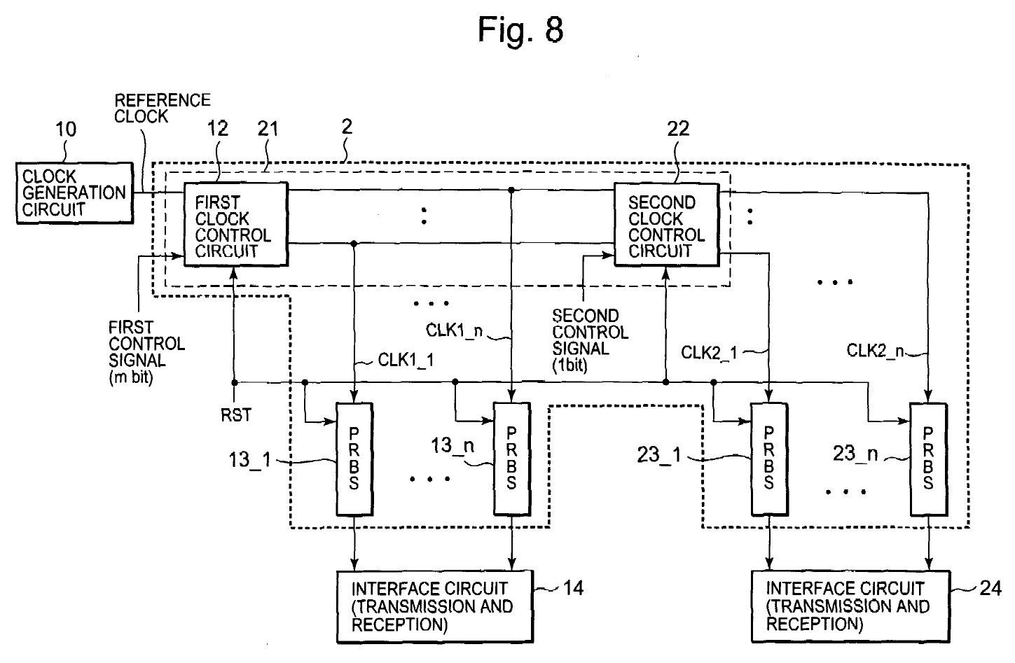

FIG. 8 shows a block diagram of a test pattern generation circuit 2 according to Embodiment 3. As shown in FIG. 8, in addition to a first clock control circuit 12 (FIG. 2), a clock control circuit 21 of the test pattern generation circuit 2 includes a second clock control circuit 22. Moreover, the test pattern generation circuit 2 includes pseudo random number generation circuits 23_1 to 23_n for the second clock control circuit 22. These pseudo random number generation circuits 23_1 to 23_n are substantially the same as the pseudo random number generation circuits 13_1 to 13_n according to Embodiment 1. In addition, interface circuits 14 and 24 are circuits to be tested, and are connected to bus wirings (not illustrated).

Here, the second clock control circuit 22 is described in detail. First clock signals CLK1_1 to CLK1_n outputted by the first clock control circuit 12 are inputted to the second clock control circuit 22. Then, the second clock control circuit 22 outputs first clock signals CLK2_1 to CLK2_n according to the inputted first clock signals CLK1_1 to CLK1_n. At this time, according to a second control signal, the second clock control circuit 22 determines whether or not to shift the output-start timings of the first clock signals CLK1_1 to CLK1_n and the output-start timings of the second clock signals CLK2_1 to CLK2_n from each other. Note that the second control signal is a 1-bit signal, and has two states that are “0” (at a low level) and “1” (at a high level).

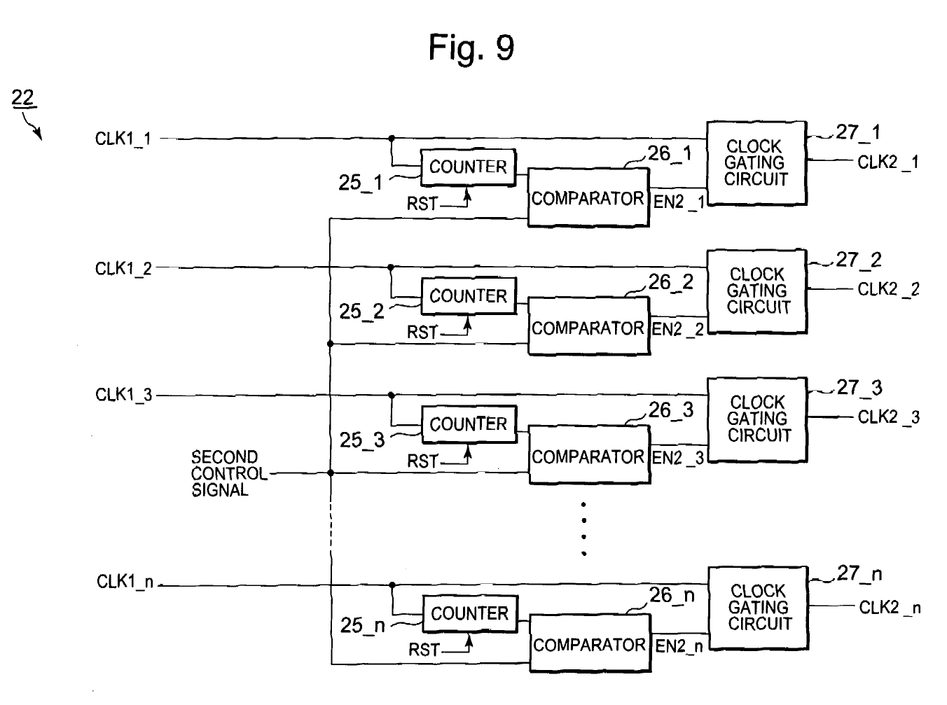

FIG. 9 shows a block diagram of this second clock control circuit 22. As shown in FIG. 9, the second clock control circuit 22 includes counters 25_1 to 25_n, comparators 26_1 to 26_n and clock gating circuits 27_1 to 27_n. The counters 25_1 to 25_n are provided corresponding to the respective first clock signals CLK1_1 to CLK1_n, and count the numbers of clocks of the first clock signals CLK1_1 to CLK1_n. In a case where the value of the second control signal is “0,” the comparators 26_1 to 26_n output the high level independently of the count value at the same time as the release of the reset. In a case where the value of the second control signal is “1,” each of the comparators 26_1 to 26_n compares a count value outputted by a correspondingly-provided one of counters 25_1 to 25_n with a predetermined mask value, and sets a corresponding one of enable signals EN2_1 to EN2_n to a high level at a time point when the count value matches with the mask value. On the other hand, in a case where the count value is smaller than the mask value, each of the comparators 26_1 to 26_n sets a corresponding one of the enable signals EN2_1 to EN2_n to a low level. In the case where the enable signals EN2_1 to EN2_n are at the high level, clock gating circuits 27_1 to 27_n output the first clock signals CLK1_1 to CLK1_n as the first clock signals CLK2_1 to CLK2_n. On the other hand, in a case where the enable signals EN2_1 to EN2_n are at the low level, the clock gating circuits 27_1 to 27_n output the low level while blocking the first clock signals CLK1_1 to CLK1_n. Note that the counters 25_2 to 25_n in this embodiment are each configured to keep a count value after the count value matches with the mask value.

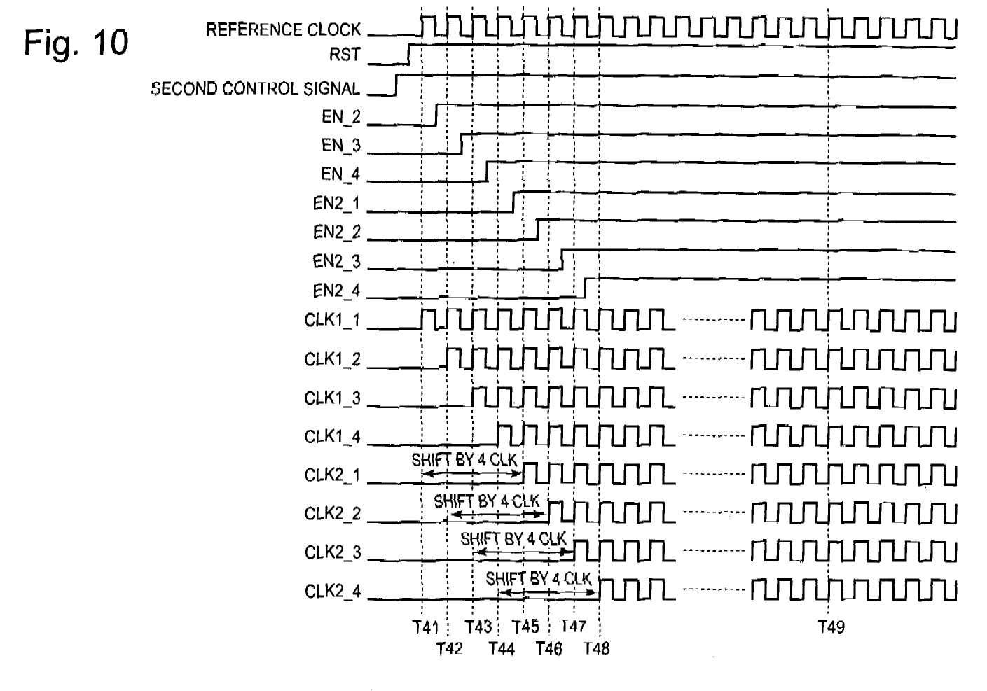

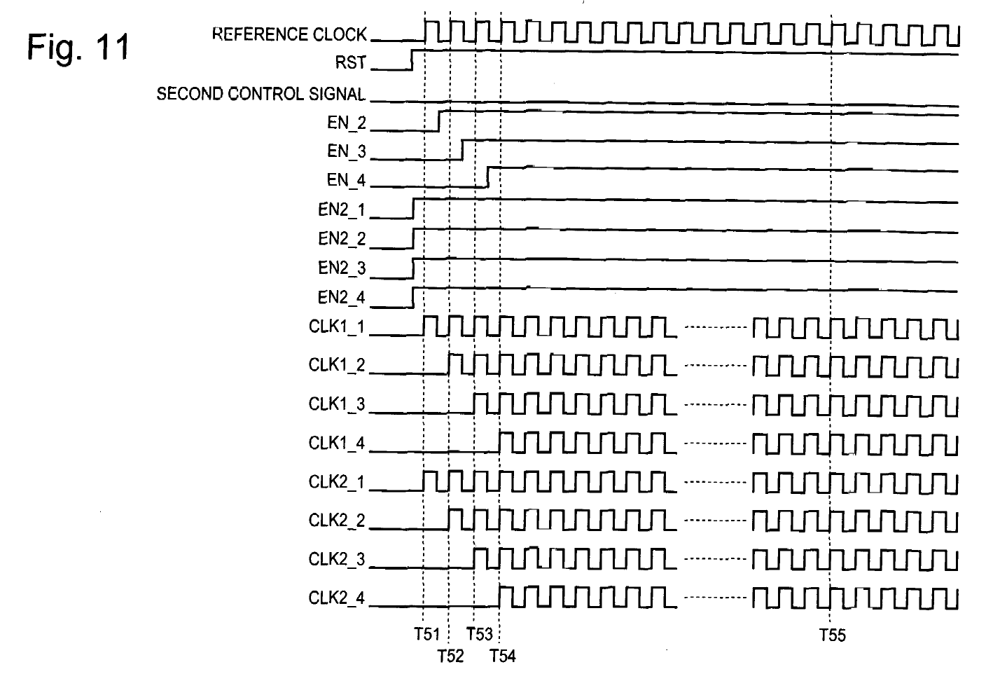

Operations of the second clock control circuit 22 are explained. FIG. 10 shows a timing chart of the operations of the second clock control circuit 22 when the second control signal is “1,” while FIG. 11 shows a timing chart of the operations of the second clock control circuit 22 when the second control signal is “0.” Incidentally, FIGS. 10 and 11 show examples dealing with a case where the circuits 14 and 24 to be tested each have a 4-channel configuration. Moreover, the first clock signals CLK1_1 to CLK1_4 in FIGS. 10 and 11 are those outputted by the first clock control circuit 12 when the value of the first control signal is “1.” In the examples shown in FIGS. 10 and 11, the mask value set in comparators 26_1 to 26_4 is “4,” and the second clock control circuit 22 outputs first clock signals CLK2_1 to CLK2_4.

In the example shown in FIG. 10, the first clock signals CLK1_1 to CLK1_4 are outputted at timings T41 to T44, respectively. At this time, the counter 25_1 counts the number of clocks of the first clock signal CLK1_1. When this count value reaches “4,” the enable signal EN2_1 outputted by the comparator 26_1 becomes the high level. Then, at the timing T45, the output of the first clock signal CLK2_1 starts. The difference between the timing T45 and the timing T41 is a time equivalent to 4 clocks of the reference clocks. As similar to the first clock signal CLK2_1, the output of each of the first clock signals CLK2_2 to CLK2_4 starts after a delay of a time period equivalent to 4 clocks of the reference clocks from a corresponding one of the first clock signals CLK1_2 to CLK2_4 (at timings T46 to T48).

In the example shown in FIG. 11, the first clock signals CLK1_1 to CLK1_4 are outputted at timings T51 to T54, respectively. At this time, even though the counter 25_1 counts the number of clocks of the first clock signal CLK1_1, the enable signal EN2_1 outputted by the comparator 26_2 becomes the high level independently of the count value. Accordingly, the output of the first clock signal CLK2_1 starts at the substantially same timing as the first clock signal CLK1_L (a timing T51). As similar to the first clock signal CLK2_1, the output of each of the first clock signals CLK2_2 to CLK2_4 starts at the substantially same timing as a corresponding one of the first clock signals CLK1_2 to CLK1_4 (at timings T52 to T54). In other words, in the case of FIG. 11 (the case where the second control signal is “0” (at the low level)), the mask value is synonymous with “0.”

In the aforementioned way, according to the value of the second control signal, the second clock control circuit 22 determines whether or not a certain shift amount is set between the output-starting timings of the first clock signals CLK1_1 to CLK1_n and the output-starting timings of the first clock signals CLK2_1 to CLK2_n.

Specifically, the adding of the second clock control circuit 22 in addition to the first clock control circuit 12 allows the clock control circuit 21 to set the output-start timing of the first clock signal having wider variations than that of the clock control circuit 11.

In this way, the test pattern generation circuit 2 according to Embodiment 3 can generate combinations of data pieces having wider variations in the bus width direction than the test pattern generation circuit 1 according to Embodiment 1.

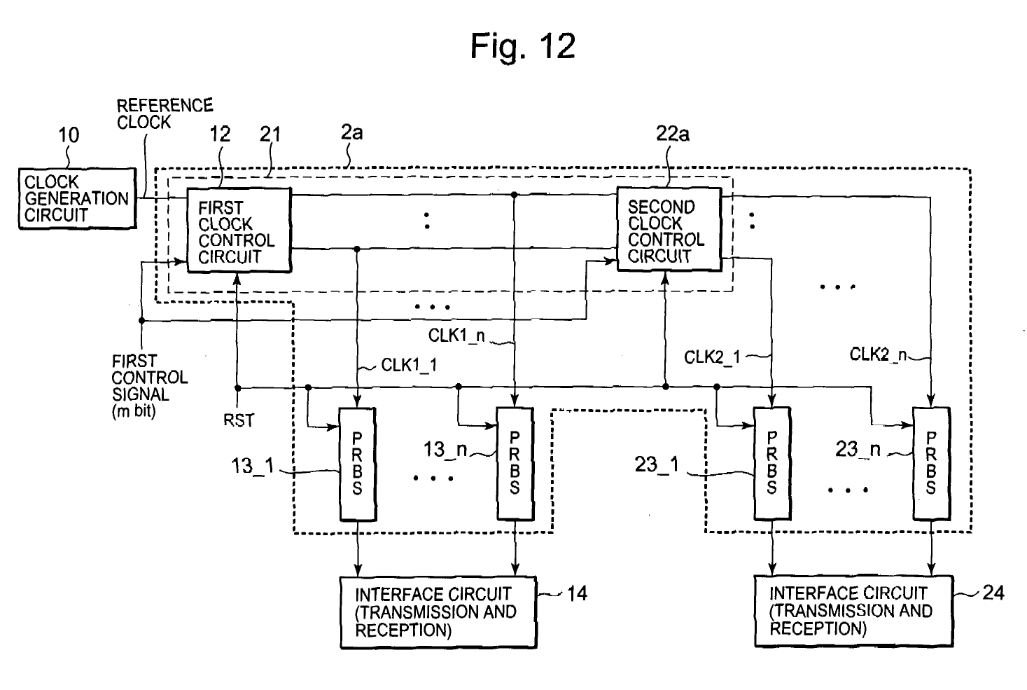

Note that the timings T49 and T55 set for the second initial values are timings at which all the pseudo random number generation circuits receive the application of the first clock signals CLK1_1 to CLK1_4 for one or more cycles, and can generate the respective pseudo random numbers as is the case with Embodiment 1. In this embodiment, assuming that the interface circuits 14 and 24 have n channels, that the first control signal is of m bits, and that the mask value of the second control circuit is L, the timing can be set to a time point after the timing at which the application of the reference clocks for cycles of at least (2^{m}−1)×(n−1)+L is completed. Moreover, the first control signal can be inputted to the second clock control circuit. FIG. 12 shows a block diagram of a test pattern generation circuit 2a in this case. The test pattern generation circuit 2a shown in FIG. 12 includes a second clock control circuit 22a. As a built-in comparator, this second clock control circuit 22a employs a comparator that is incorporated in the first clock control circuit.

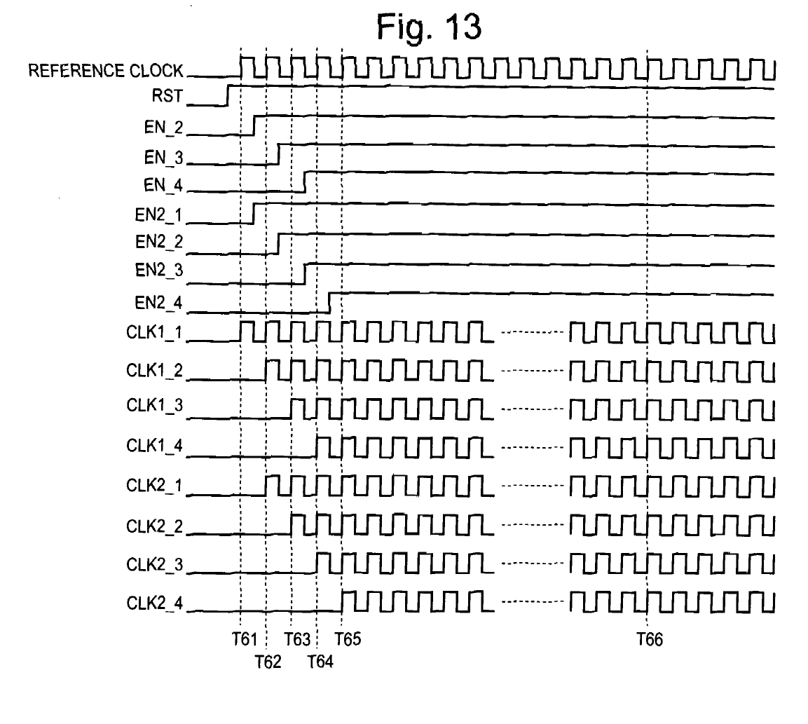

FIG. 13 shows a timing chart of operations of this second clock control circuit 22a. The timing chart shown in FIG. 13 indicates the case where the value of the first control signal is “1.” As shown in FIG. 13, in this case, the output of the first clock signal CLK2_1 starts after a delay of a time period equivalent to one clock of the reference clock from the first clock signal CLK1_L (at a timing T62). The output of each of the first clock signals CLK2_2 to CLK2_4 starts after a delay of a time period equivalent to one clock of the reference clock from a corresponding input of the first clock signals CLK1_1 to CLK14 (at timings T63 to T65).

In this way, by inputting the first control signal to the second clock control circuit, the output-start timings of the first clock signals can also have wide variations. In other words, the first clock control circuit and the second clock control circuit constituting the clock control circuit can be configured by using either the control using the first control signal having a multi-bit structure, or the control using the second control signal having a 1-bit structure. Accordingly, the clock control circuit may have a clock control circuit using at least any one of the control signals.

### Embodiment 4

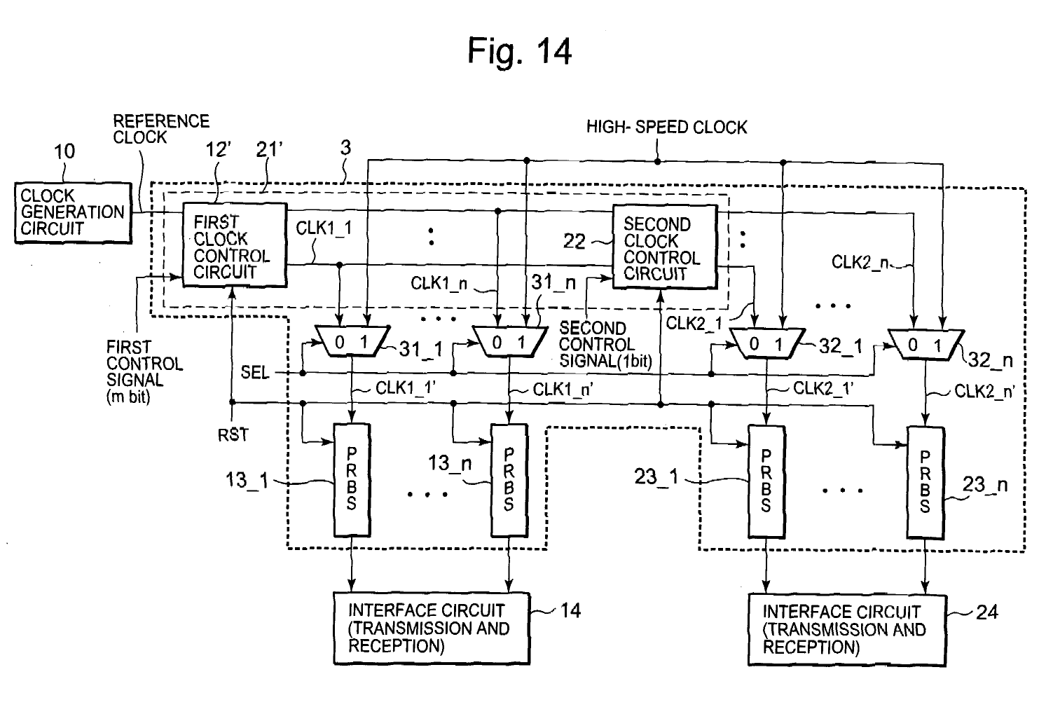

A test pattern generation circuit 3 according to Embodiment 4 is one obtained by adding selectors 31_1 to 31_n and 32_1 to 32_n to the test pattern generation circuit 2 according to Embodiment 3, and by replacing the first clock control circuit 12 with the first clock control circuit 12′ shown in Embodiment 2. FIG. 14 shows a block diagram of the test pattern generation circuit 3. The selectors 31_1 to 31_n and 32_1 to 32_n are correspondingly connected to the respective output terminals of a clock control circuit 21′. Moreover, the output terminals of the selectors 31_1 to 31_n and 32_1 to 32_n are correspondingly connected to the respective pseudo random number generation circuits 13_1 to 13_n and 23_1 to 23_n. Each of the selectors. 31_1 to 31_n and 32_1 to 32_n selects and outputs any one of two input signals according to the value of the selecting signal SEL.

In this embodiment, each of the first clock signals CLK1_1 to CLK1_n and CLK2_1 to CLK2_n is inputted to one of the inputs of a corresponding one of the selectors 31_1 to 31_n and 32_1 to 32_n and a test clock is inputted to the other input.

The test clock may be the same as the reference clock as in Embodiment 1, or may be a high-speed clock. Here, in this embodiment, a high-speed clock is applied as the test clock, and an operation clock (for example, a clock speed=533 MHz for communications with an external memory) under normal use conditions in a semiconductor device on which the test pattern generation circuit 3 is mounted is used as the high-speed clock. In addition, the high-speed clock is a clock reaching each of the pseudo random number generation circuits and having with skew adjusted.

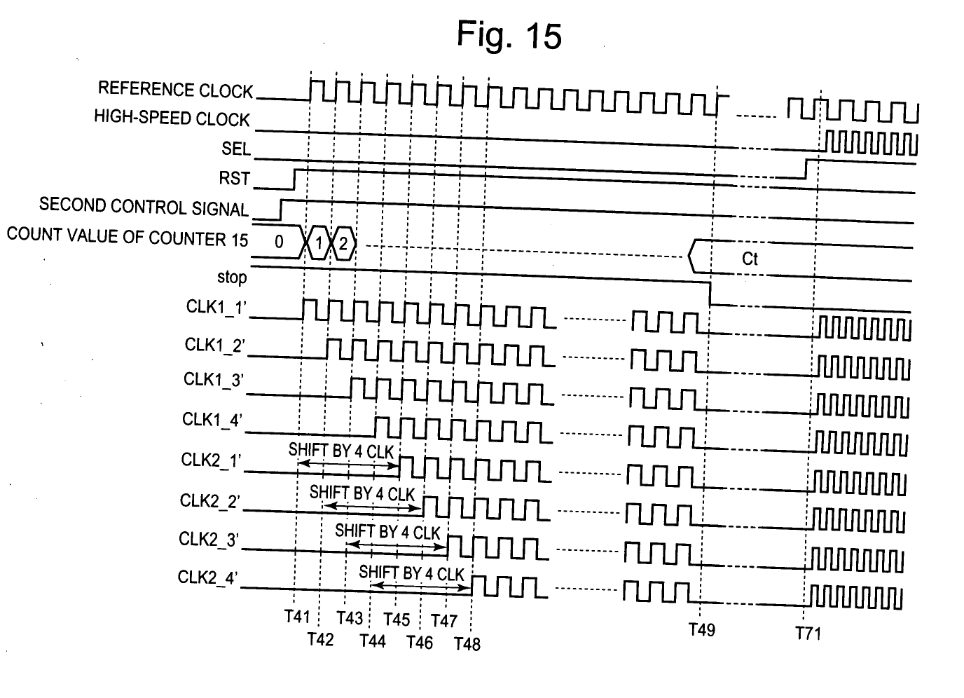

Here, FIG. 15 shows a timing chart indicating operations of the test pattern generation circuit 3. In the example shown in FIG. 15, since the selecting signal SEL is kept at the low level until a timing T49, the clock control circuit 21′ performs the same operation as in the timing chart shown in FIG. 10. Then, at the timing 49, the second initial values of the pseudo random number generation circuits 13_1 to 13_n and 23_1 to 23_n are set. Thereafter, before a test starts at a timing T71, the selecting signal SEL is set to the high level, and thereby the high-speed clocks inputted after the timing T71 are supplied to the pseudo random number generation circuits 13_1 to 13_n and 23_1 to 23_n. Thus, the pseudo random number generation circuits 13_1 to 13_n and 23_1 to 23_n output pseudo random number data sequences in synchronization with the high-speed clocks.

Incidentally, in a case where a timing of the selecting signal SEL for the high-speed clocks can be designed well, it is possible to employ a configuration in which the high-speed clocks are continuously applied to the selectors 31_1 to 31_n and 32_1 to 32_n from the beginning, and in which the switching is carried out in synchronization with the high-speed clocks at the timing T71. Moreover, a third clock control circuit may be configured by replacing, as a built-in comparator, the comparator incorporated in the second clock control circuit 22 with the comparator incorporated in the first clock control circuit 12′ as is similar to Embodiment 3. Then, both of the first and third clock control circuits may be controlled with the first control signal. Alternatively, a fourth clock control circuit may be configured by reversely replacing, as an built-in comparator, the comparator incorporated in the first clock control circuit 12′ with the comparator incorporated in the second clock control circuit 22. Then, both of the second and fourth clock control circuits may be controlled with the second control signal.

According to the above description, the test pattern generation circuit 3 can generate test patterns at clock frequency depending on the operation speed of a semiconductor device. Accordingly, actual operations of the semiconductor device can be checked, thereby improving the reliability of the semiconductor device.

### Embodiment 5

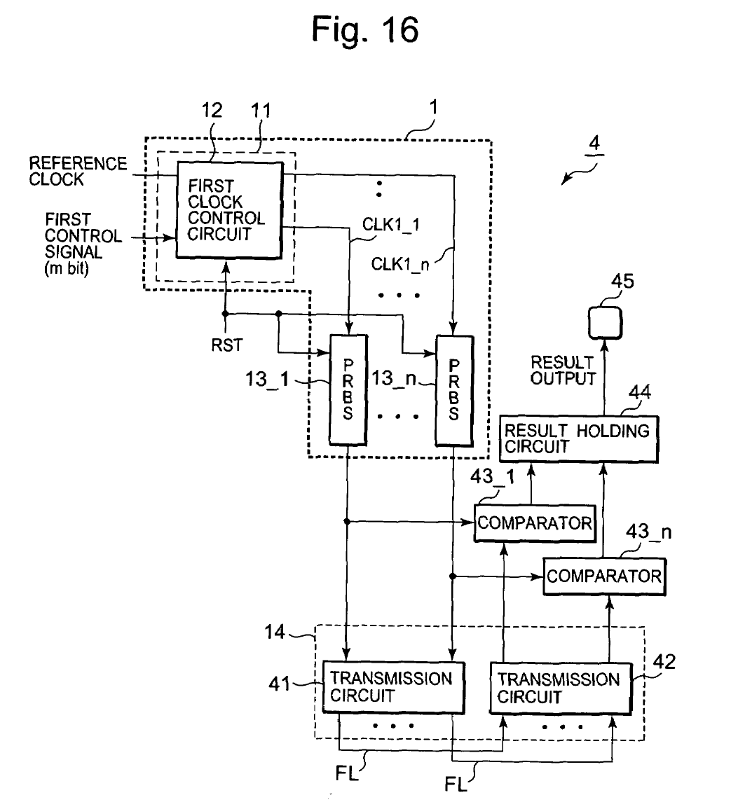

In Embodiment 5, a test circuit 4 having the test pattern generation circuit 1 of Embodiment 1 will be explained. FIG. 16 shows the test circuit 4. Besides the test pattern generation circuit 1, the test circuit 4 includes an interface circuit 14, comparators 43_1 to 43_n, a result holding circuit 44 and a test terminal 45.

The interface circuit 14 includes a transmission circuit 41 and a receiving circuit 42. The transmission circuit 41 and the receiving circuit 42 are connected to each other with a wiring FL. Thereby, signals transmitted from the transmission circuit 41 are received by the receiving circuit 42.

The comparators 43_1 to 43_n are provided corresponding to the respective signal lines of the bus wiring connected to the interface circuit 14. In other words, the number of the comparators 43_1 to 43_n is equal to the number of pseudo random number generation circuits 13_1 to 13_n. The comparators 43_1 to 43_n compare test patterns outputted by the pseudo random number generation circuits 13_1 to 13_n with test patterns inputted through the interface circuit 14. The result holding circuit 44 holds a test result of each of the test patterns. The test terminal 45 is a terminal for taking out the test results.

Operations of the test circuit 4 are described. First of all, the setting of the second initial values is completed in the test pattern generation circuit 1. After that, when a test starts, the comparators 43_1 to 43_n output the test results based on comparison results between test patterns outputted by the pseudo random number generation circuits 13_1 to 13_n and test patterns inputted through the interface circuit 14. This test result indicates OK when the values of two patterns match with each other, and NG when the values of two patterns do not match. Then, the test results are held in the result holding circuit 44. The held test results are taken out through the test terminal 45 after the test is completed.

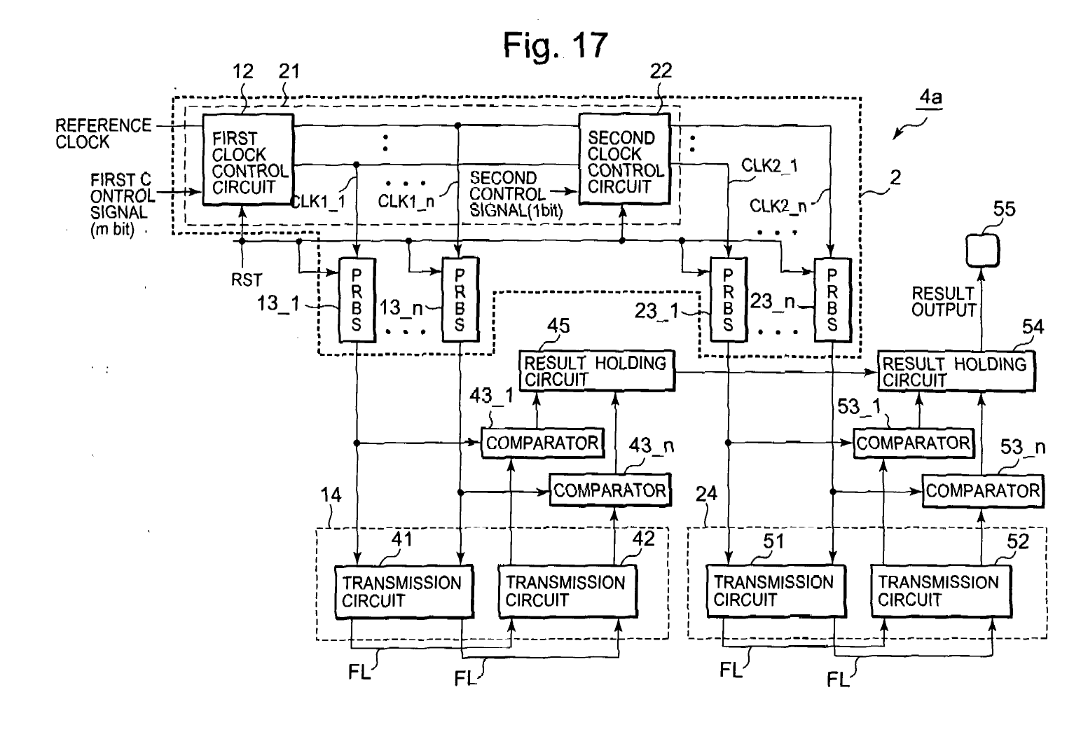

As described above, the test circuit according to this embodiment enables use of test patterns having high randomness in the data sequence direction and in the bus width direction, the test patterns generated in the test pattern generation circuit 1. This makes it possible to perform a test having a high coverage including a detection of not only a circuit defect but also a crosstalk defect. Incidentally, the test pattern generation circuit 1′, the test pattern generation circuit 2 or the test pattern generation circuit 3 may be employed for the test circuit 4. FIG. 17 shows a block diagram in a case where the test pattern generation circuit 2 is employed as one example for the test circuit 4. Although Embodiments 3, 4 and 5 each use the two circuits (the interface circuits 14 and 24) to be tested, it is possible to implement a configuration in which test patterns are generated and then provided to a certain number of circuits to be tested, by adding the first and second clock control circuits according to the number of circuits to be tested.

The present invention has been described based on the above examples, but the present invention is not limited only to the above examples, and includes various kinds of alterations and modifications that could be achieved by a person skilled in the art within the scope of the invention of each of claims of this application as a matter of course.

Further, it is noted that, Applicant's intent is to encompass equivalents of all claim elements, even if amended later during prosecution.

What is claimed is:

1. A test pattern generation circuit, comprising:
a plurality of pseudo random number generation circuits which are provided respectively corresponding to signal lines in a bus wiring, which each have a first initial value set to be the same value in advance, and which generates pseudo random numbers having the first initial value as a starting value in response to a first clock signal; and
a clock control circuit that determines, according to a value of a control signal, each of output-start timings of the first clock signals respectively provided to the plurality of pseudo random number generation circuits.

2. The test pattern generation circuit according to claim 1, wherein the pseudo random number generation circuits each comprise a shift register with feedback via an exclusive OR circuit.

3. The test pattern generation circuit according to claim 2,
wherein the clock control circuit includes a first clock control circuit, which receives reference clocks as an input signal, and sets, according to the value of the control signal, a shift amount in timings of starting supply of the first clock signals to the plurality of pseudo random number generation circuits.

4. The test pattern generation circuit according to claim 2,
wherein the clock control circuit includes a first clock control circuit which receives reference clocks as an input signal, which determines whether to output the reference clock signal by using a shift amount in timings of starting supply of the first clock signals to the plurality of pseudo random number generation circuits, according to the control signal, the shift amount being set in advance.

5. The test pattern generation circuit according to claim 3,
wherein the clock control circuit includes a second clock control circuit which receives the first clock signal as an input signal, and sets, according to the value of the control signal, a shift amount in timings of starting supply of the first clock signals to the plurality of pseudo random number generation circuits.

6. The test pattern generation circuit according to claim 3,
wherein the clock control circuit includes a second clock control circuit which receives the first clock as an input signal, which determines whether to output the reference clock signal by using a shift amount in timings of starting supply of the first clock signals to the plurality of pseudo random number generation circuits, according to the control signal, the shift amount being set in advance.

7. The test pattern generation circuit according to claim 5, wherein the clock control circuit is connected to circuits to be tested, each of said circuits to be tested respectively corresponding to the first clock control circuit and the second clock control circuit.

8. The test pattern generation circuit according to claim 3, wherein:
the first clock control circuit includes a first counter and a clock gating circuit;
the first counter counts a number of clocks of the reference clocks, and outputs a stop signal when the counted value reaches a predetermined value; and
the clock gating circuit receives the reference clocks and outputs the reference clocks as the first clock signal, until receiving the stop signal.

9. The test pattern generation circuit according to claim 5, wherein the second clock control circuit receives, as an input, the first clock signals outputted by the first clock control circuit.

10. The test pattern generation circuit according to claim 2, wherein,
the control signal includes at least one of a first control signal and a second control signal,
under control based on the first control signal, the clock control circuit sets, according to a value of the first control signal, a shift amount in timings of starting supply of the first clock signals to the plurality of pseudo random number generation circuits,
under control based on the second control signal, the clock control circuit determines whether to output the reference clock signal by using a shift amount in supply starting timings set in advance.

11. The test pattern generation circuit according to claim 1, further comprising a selector which selects one of the first clock signal and a second clock signal, and provides the selected clock signal to each of the plurality of pseudo random number generation circuits.

12. The test pattern generation circuit according to claim 1,
wherein the plurality of pseudo random number generation circuits each have a second initial value set to a certain value based on the first initial value and the first clock signal, and each output, as the test patterns, pseudo random numbers having the second initial value as a starting value.

13. A test circuit, comprising:
the test pattern generation circuit according to claim 1;
a comparator that compares pseudo random numbers inputted from an interface circuit, with pseudo random numbers outputted by the plurality of pseudo random number generation circuits in the test pattern generation circuit; and
a result holding circuit that holds test results outputted by the comparator and outputting the test results.

14. A test pattern generation circuit, comprising:
a clock control circuit which outputs a plurality of clock signals, each of said clock signals being outputted at a timing based on a control signal; and
a plurality of pseudo random number generation circuits, which each have the same initial value, and which each generates pseudo random numbers having the initial value as a starting value in response to a corresponding one of said clock signals.

15. The test pattern generation circuit as claimed in claim 14, wherein said clock control circuit comprises:
a first counter which counts a reference clock;
a first comparator which compares an output of said first counter with a value of said control signal and outputs a first enable signal when the output of said first counter and said value of said control signal are matched; and
a first clock gating circuit which outputs said reference signal as a first one of said clock signals when said first enable signal is inputted.

16. The test pattern generation circuit as claimed in claim 15, wherein said clock control circuit further comprises:
a second counter which counts said first one of said clock signals;
a second comparator which compares an output of said second counter with a value of said control signal and outputs a second enable signal when the output of said second counter and said value of said control signal are matched; and
a second clock gating circuit which outputs said first one of said clock signals as a second one of said clock signals when said second enable signal is inputted.

17. The test pattern generation circuit as claimed in claim 16, further comprising:
a selector which selectively outputs one of said clock signals or a test clock.

18. The test pattern generation circuit as claimed in claim 14, wherein said clock control circuit comprises:
a first counter which counts a reference clock and outputs a stop signal when a counted number reaches a predetermined number;
a first clock gating circuit which outputs said reference signal as one of said clock signals and stops outputting said reference signal when said stop signal is inputted;
a second counter which counts said one of said clock signals;
a comparator which compares an output of said second counter with a value of said control signal and outputs an enable signal when the output of said second counter and said value of said control signal are matched; and
a clock gating circuit which outputs said one of said clock signals as a second one of said clock signals when said enable signal is inputted.

19. The test pattern generation circuit as claimed in claim 14, further comprising:
a second clock control circuit which receives the clock signals and outputs a plurality of second clock signals, each of said second clock signals being outputted at a timing based on a second control signal; and
a plurality of second pseudo random number generation circuits, which each has the same initial value, and which each generates pseudo random numbers having the initial value as a starting value in response to a corresponding one of said second clock signals.

20. The test pattern generation circuit as claimed in claim 19, wherein, said second clock control circuit comprises a plurality of clock gating circuits which receive the respective one of clock signals.
